(19) United States
(12) Patent Application Publication
(10) Pub. No.: US 2025/0140679 A1
(43) Pub. Date: May 1, 2025

(54) ELECTRONIC PACKAGE ASSEMBLY AND METHODS FOR FORMING THE SAME

(71) Applicant: JCET STATS ChipPAC Korea Limited, Incheon (KR)

(72) Inventors: SangHoon LEE, Incheon (KR); SeungHyun LEE, Incheon (KR); HeeSoo LEE, Incheon (KR)

(21) Appl. No.: 18/929,640

(22) Filed: Oct. 29, 2024

(30) Foreign Application Priority Data
Oct. 30, 2023 (CN) 202311425467.6

(51) Int. Cl. H01L 23/498; H01L 21/48; H01L 21/56; H01L 23/00; H01L 23/31; H01L 23/66; H01L 25/16

(52) U.S. Cl. CPC H01L 23/49838; H01L 21/4853; H01L 21/565; H01L 23/3121; H01L 23/49833; H01L 23/66; H01L 24/16; H01L 25/16; H01L 2223/6677; H01L 2224/16225; H01L 2924/1815

(57) ABSTRACT

A method for forming an electronic package assembly is provided. The method comprises: providing a base package substrate, wherein the base package substrate comprises a first package substrate, a second package substrate and an interconnect portion, and wherein first and second sets of conductive patterns are both formed on a front surface of the base package substrate; attaching a flexible cable linkage onto the front surface of the base package substrate and across the interconnect portion to electrically connect the first set of conductive patterns with the second set of conductive patterns; attaching a mold chase on the front surface of the base package substrate; forming a first mold cap within the first cavity and a second mold cap within the second cavity; and removing the interconnect portion from the base package substrate.

### TECHNICAL FIELD

The present application generally relates to semiconductor packaging technology, and more particularly, to an electronic package assembly and methods for forming the same.

### BACKGROUND OF THE INVENTION

The semiconductor industry is constantly faced with complex integration challenges as consumers want their electronics to be smaller, faster and higher performance with more and more functionalities packed into a single device. In recent years, Antenna-in-Package (AiP) devices with System-in-Package (SiP) and antennas integrated into one package have been adopted for various portable multimedia devices such as mobile handsets. However, different molding materials may be used to encapsulate various electronic components such as antennas and semiconductor chips based on the requirements of the electronic components. As a result, electronic packages encapsulating the different electronic components may need to be fabricated separately and then be assembled together, which leads to a more complex fabrication process and a higher cost.

Therefore, a need exists for a method for forming an electronic package assembly with a simplified fabrication process and a reduced cost.

### SUMMARY OF THE INVENTION

An objective of the present application is to provide a method for forming an electronic package assembly with a simplified fabrication process and a reduced cost.

According to an aspect of the present application, a method for forming an electronic package assembly is provided. The method comprises: providing a base package substrate, wherein the base package substrate comprises a first package substrate having a first set of conductive patterns, a second package substrate having a second set of conductive patterns, and an interconnect portion between the first package substrate and the second package substrate, and wherein the first and second sets of conductive patterns are both formed on a front surface of the base package substrate; attaching a flexible cable linkage onto the front surface of the base package substrate and across the interconnect portion to electrically connect the first set of conductive patterns with the second set of conductive patterns; attaching a mold chase having a first cavity and a second cavity on the front surface of the base package substrate to align the first cavity with the first package substrate and align the second cavity with the second package substrate; forming a first mold cap within the first cavity and a second mold cap within the second cavity by injecting into the first cavity and the second cavity respective molding materials, wherein the first mold cap is isolated from the second mold cap by the interconnect portion of the base package substrate; and removing the interconnect portion from the base package substrate.

According to another aspect of the present application, an electronic package assembly is provided. The electronic package assembly comprises: a first package, comprising: a first package substrate having a first set of conductive patterns formed on a front surface of the first package substrate; and a first mold cap formed on the front surface of the first package substrate and encapsulating the first set of conductive patterns; a second package separated from the first package, the second package comprising: a second package substrate having a second set of conductive patterns formed on a front surface of the second package substrate; and a second mold cap formed on the front surface of the second package and encapsulating the second set of conductive patterns; and a flexible cable linkage comprising a first end attached on the front surface of the first package substrate and encapsulated by the first mold cap, and a second end attached on the front package of the second package substrate and encapsulated by the second mold cap, the flexible cable linkage electrically connecting the first set of conductive patterns with the second set of conductive patterns.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1K illustrate various steps of a method for forming an electronic package assembly according to a first embodiment of the present application.

FIGS. 2A to 2C illustrate a portion of various steps of a method for forming an electronic package assembly according to a second embodiment of the present application.

FIGS. 3A and 3B illustrate a portion of various steps of a method for forming an electronic package assembly according to a third embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, in typical AiP devices, an electronic package with built-in semiconductor chip(s) or some other components and antenna(s) are integrated into one package or package assembly. However, due to the different requirements of these components and antennas, different molding materials may be used in the electronic package. As a result, electronic packages encapsulating the different electronic components may need to be fabricated separately and then be assembled together, which leads to a more complex fabrication process and a higher cost.

To address this issue, a new method for forming an electronic package assembly is provided, in which the electronic packages encapsulating different electronic components may be fabricated at the same time and may also be attached onto external devices together at once, thus simplifying its fabrication process and reducing the fabrication cost.

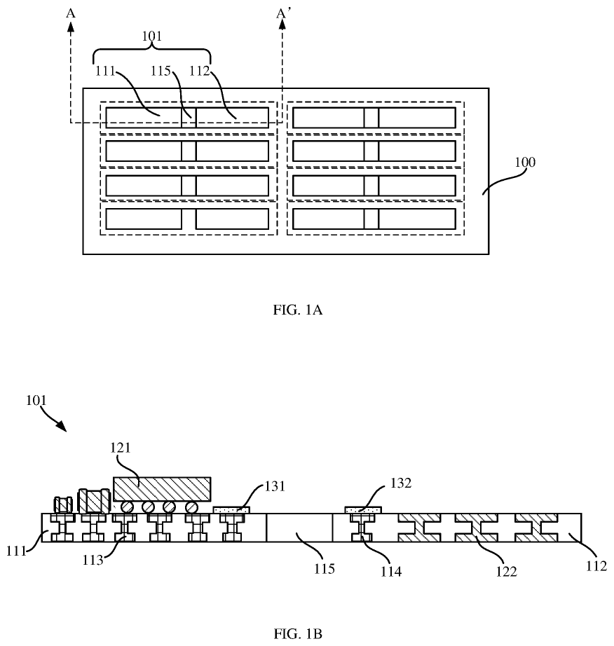

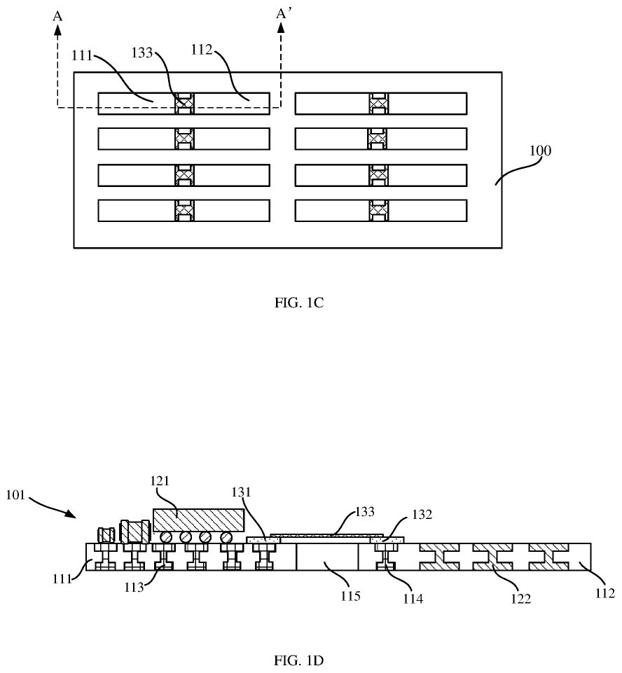

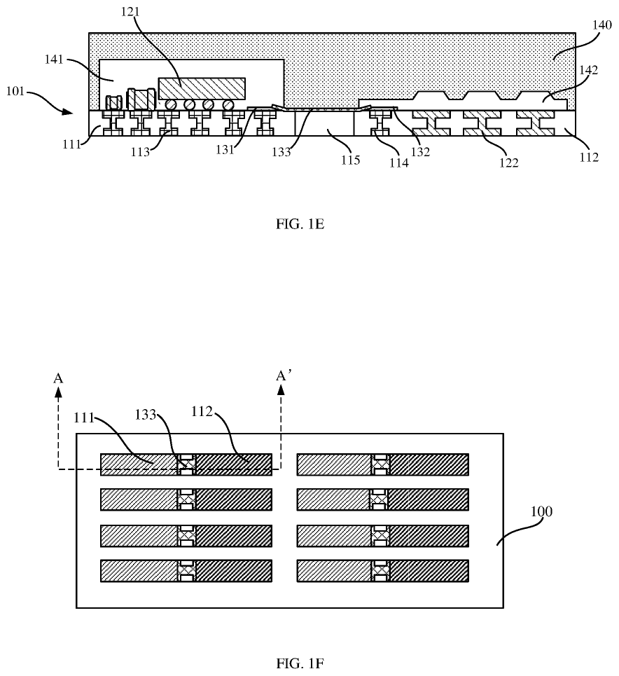

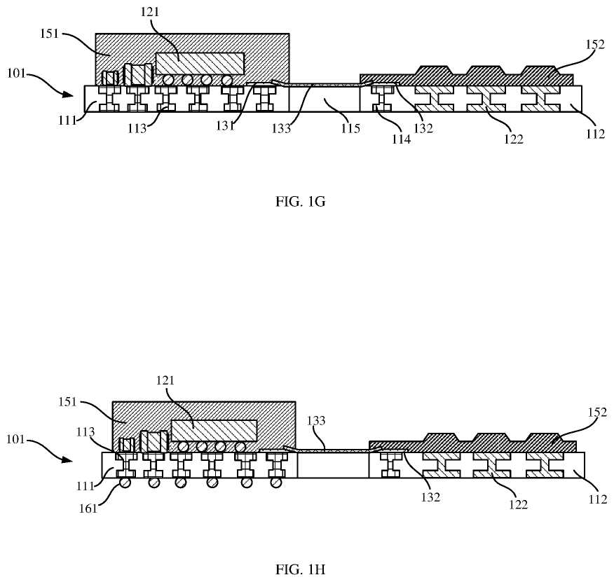

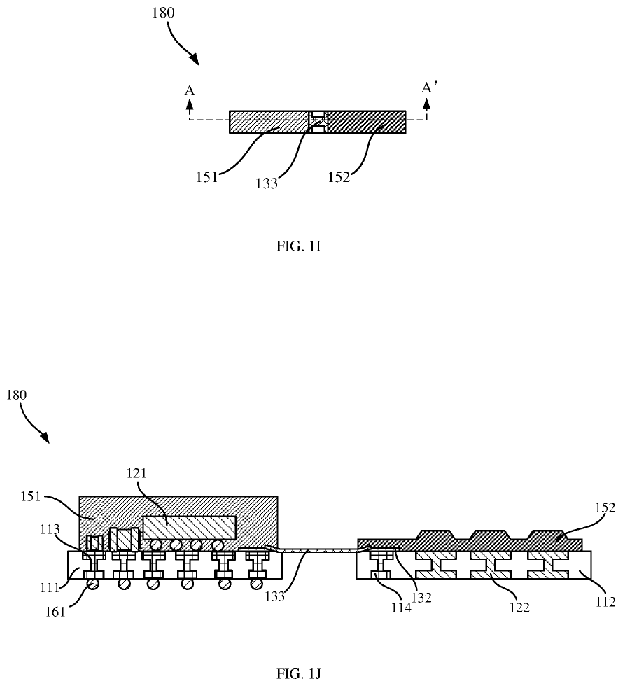

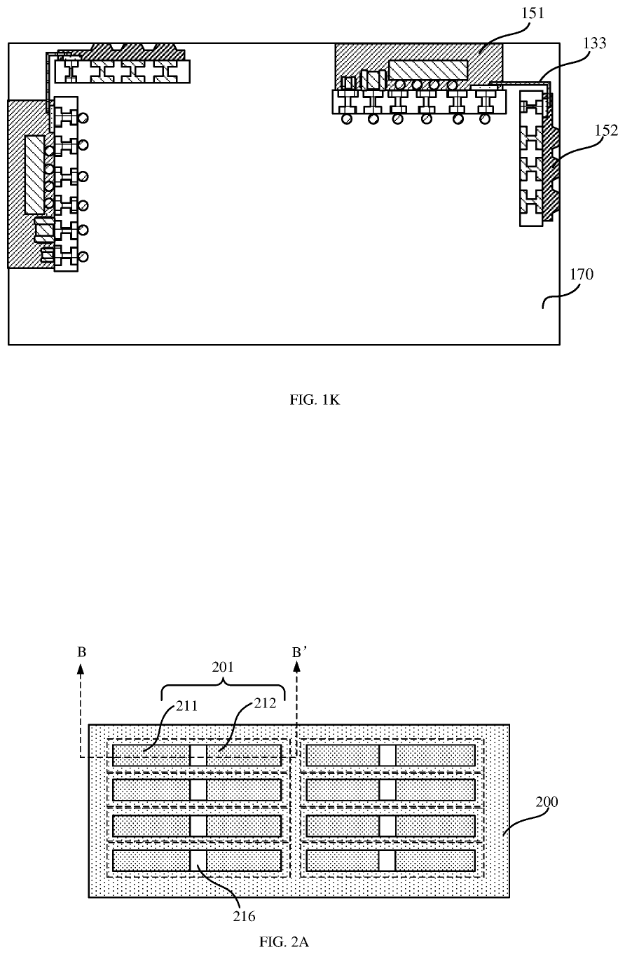

FIGS. 1A to 1K illustrate various steps of a method for forming an electronic package assembly according to a first embodiment of the present application. In the following, the method will be described with reference to FIGS. 1A to 1K in more details.

As can be appreciated, a plurality of units of package substrates may be provided in a package substrate strip such that a plurality of electronic package assemblies may be formed using the same processing. In this embodiment, each of the units of package substrates may have the same or similar structure, which may be referred to as a base package substrate. FIG. 1A is a top view of the package substrate strip 100 and FIG. 1B is a cross-sectional view of one of the base package substrates 101 along line AA′ shown in FIG. 1A.

As shown in FIGS. 1A and 1B, the base package substrate 101 includes a first package substrate 111 with embedded interconnect wires 113, a second package substrate 112 with embedded interconnect wires 114, and an interconnect portion 115 between the first package substrate 111 and the second package substrate 112. The first package substrate 111 further includes a first set of conductive patterns 131 which are formed on a front surface of the first package substrate 111, and the second package substrate 112 further includes a second set of conductive patterns 132 which are formed on a front surface of the second package substrate 112. The first and second sets of conductive patterns 131, 132 are both adjacent to the interconnect portion 115 of the base package substrate 101. For example, the first set of conductive patterns 131 are closer to the interconnect portion 115 compared with the other components mounted on the front surface of the first package substrate 111. Also, the second set of conductive patterns 132 are closer to the interconnect portion 115 compared with the other electronic components that are also embedded within the second package substrate 112. In some embodiments, the first set of conductive patterns 131 may be hundreds of microns to several millimeters to a boundary between the first package substrate 111 and the interconnect portion 115. Similarly, the second set of conductive patterns 132 may be hundreds of microns to several millimeters to a boundary between the second package substrate 112 and the interconnect portion 115. It should be noted that the structures formed on the first package substrate 111 and the second package substrate 112 according to FIG. 1B are omitted in FIG. 1A for simplicity.

In some embodiments, the first and second sets of conductive patterns 131, 132 may include several conductive pads (e.g., copper pads), and be electronically connected with the embedded interconnect wires 113, 114 within the first and second package substrate 111, 112, respectively. Although not shown in FIG. 1B, the other electronic component formed on or in the second package substrate 112 may be electrically connected to the second set of conductive patterns 132, for example, through the interconnect wires 114. In this way, the electronic components mounted on or formed in the package substrate 111, 112 can be accessed through the conductive patterns 131 and 132.

In the embodiment shown in FIG. 1A, each base package substrate 101 is surrounded by certain insulation areas such as saw streets so as to be separated from the other base package substrates 101. The units of the package substrate strip 100, i.e., the base package substrates 101, form an array with multiple rows and columns. However, it can also be appreciated that the units of the package substrate strip 100 may have various arrangements and structures according to the specific layouts of the electronic package assemblies to be formed.

In particular, at least one first-type electronic component 121 may be mounted on the front surface of the first package substrate 111 which is electronically connected with the embedded interconnect wires 113. The at least one first-type electronic component 121 may include various types of electronic devices, such as semiconductor chips, resistors, capacitors or the like. In some embodiments, the first-type electronic component(s) 121 may be electrically connected with interconnect wires 113 via a plurality of solder bumps. Additionally, in the embodiment shown in FIG. 1B, the at least one second-type electronic component 122 may be mounted in the second package substrate 112, which may include one or more antennas, for example. In some other embodiments, the at least one second-type electronic component 122 may be mounted on the front surface of the second package substrate 112, for example, via solder bumps.

In the embodiment, the first-type electronic component 121 and the second-type electronic component 122 mounted on the respective package substrates 111 and 112 may have different requirement on encapsulation and thus different molding materials may be used. Furthermore, in order to improve the mounting of the electronic package assembly to be formed on an external device or substrate, a flexible link may be desired between the package substrates 111 and 112, instead of the interconnect portion 115, which may be formed of the same material with the package substrates 111 and 112 that are relatively rigid and not bendable. In the following, the steps to form the flexible link between the package substrates 111 and 112 will be elaborated.

Next, a flexible cable linkage 133 is attached onto the front surface of the base package substrate 101 and across the interconnect portion 115 to electrically connect the first set of conductive patterns 131 with the second set of conductive patterns 132. FIG. 1C is a top view of the package substrate strip 100 with structures thereon and FIG. 1D is a cross-sectional view of the base package substrate 101 along line AA′ shown in FIG. 1C. As shown in FIGS. 1C and 1D, a first end of the flexible cable linkage 133 is attached on the front surface of the first package substrate 111, and a second end of the flexible cable linkage 133 is attached on the front surface of the second package substrate 112. It should be noted that the above-mentioned process and some or all of the following processes are exemplarily described with reference to one of the base package substrates 101, however, the same or similar process may be applied to the other base package substrates 101 of the package substrate strip 100. For example, as shown in FIG. 1C, various flexible cable linkages 133 are attached onto the package substrate strip 100, each of which is aligned with and substantially covers one interconnect portion 115.

Still referring to FIG. 1D, the flexible cable linkage 133 may have built-in cables or wires that can electronically connect the first set of conductive patterns 131 with the second set of conductive patterns 132, and thus the first package substrate 111 and the second package substrate 112 can be electrically connected with each other, forming an integrated electronic device. In some embodiment, the flexible cable linkage 133 may have sufficient flexibility to be bend into any shape according to the various layout of the electronic package assembly to be formed. At the same time, the flexible cable linkage 133 should also provide reliable electronic connection between the first and second sets of conductive patterns 131 and 132. In some embodiments, the flexible cable linkage 133 may include electronic cables or wires which are wrapped by a protective coating. The electronic cables or wires may be formed from a metallic material such as copper, and the protective coating may be formed from a polymeric material, e.g., polyimide, with desired flexibility and wear-resisting characteristics. In some embodiments where the conductive patterns 131 and 132 may protrude from and be higher than the front surfaces of the package substrates 111 and 112, a gap may exist between the flexible cable linkage 133 and the front surface of the interconnect portion 115. The flexibility of the flexible cable linkage 133 may allow at least a part (e.g., its middle portion) of the flexible cable linkage 133 to be pressed downward against the front surface of the interconnect portion 115 by an external pressure and prevent crack or breakage of the flexible cable linkage 133. However, it can be appreciated that in some other embodiments, the conductive patterns 131 and 132 may be flush with the front surfaces of the package substrates 111 and 112, and thus the flexible cable linkage 133 may be in contact with the interconnect portion 115 when attached onto the front surface of the base package substrate 101. In some embodiments, the flexible cable linkage 133 may be loosely attached onto the front surface of the base package substrate 101 to avoid breakage during subsequent processing.

Next, as shown in FIG. 1E, a mold chase 140 for molding and encapsulation is attached on the front surface of the base package substrate 101. It can be appreciated that the base package substrate 101 may be placed on a platform (not shown). The mold chase 140 includes a first cavity 141 and a second cavity 142 which are aligned with the first package substrate 111 and the second package substrate 112, respectively. The first cavity 141 and second cavity 142 may determine positions and shapes of a first mold cap and a second mold cap to be formed subsequently on the base package substrate 101. In the embodiment shown in FIG. 1E, the first cavity 141 may be used to accommodate the first-type electronic components 121, the first set of conductive patterns 131 and the first end of the flexible cable linkage 133. The second cavity 142 may be used to accommodate the second-type electronic components 122, the second set of conductive patterns 132 and the second end of the flexible cable linkage 133. Furthermore, the second-type electronic component 122 includes one or more antennas, and accordingly the second cavity 142 may include one or more stages each aligned with one of the one or more antennas. In this embodiment, the stages may be shaped as a truncated pyramid. Such shaped second cavity 142 above the antennas may improve a transmission and reception rate of the antennas after the second mold cap is formed on the surface of the second package substrate 112. In some other embodiments, the second cavity 142 above the antennas may have a variety of shapes such as trapezium, diamond, hemisphere, semi-elliptical, or lens shape.

Furthermore, when viewed in the lengthwise direction as shown in FIG. 1E, the first cavity 141 and the second cavity 142 are isolated from each other by the mold chase 140 at the interconnect portion 115. In particular, when the mold chase 140 is attached onto the base package substrate 101, a bottom surface of the mold chase 140 may contact a top surface of the flexible cable linkage 133, and then the mold chase 140 may compress the flexible cable linkage 133 against the base package substrate 101. Due to the pressure applied by the mold chase 140, the central portion of the flexible cable linkage 133 may deform and slightly move downward to contact the top surface of the interconnect portion 115. After the attachment of the mold chase 140 onto the base package substrate 101, the flexible cable linkage 133 is clamped between the mold chase 140 and the interconnection portion 115, which may serve as a part of the isolation between the first cavity 141 and the second cavity 142. As mentioned above, due to the flexibility of the flexible cable linkage 133, the pressure applied by the mold chase 140 may not break the flexible cable linkage 133 but may improve the isolation during a subsequent molding process, as will be elaborated below.

Next, a first mold cap is formed within the first cavity 141 and a second mold cap is formed within the second cavity 142 by, for example, injecting into the first cavity 141 and the second cavity 142 respective molding materials. In some embodiments, the molding materials injected into the first cavity 141 and the second cavity 142 may be the same, but in some other embodiments, the molding materials may be different. After the formation of the first mold cap and the second mold cap, the mold chase 140 is removed from the base package substrate 101. FIG. 1F is a top view of the package substrate strip 100 and structures thereon, and FIG. 1G is a cross-sectional view of a base package substrate 101 and structures thereon along line AA′ shown in FIG. 1F.

As shown in FIGS. 1F and 1G, the first mold cap 151 covers respective top surfaces of the first-type electronic components 121, the first set of conductive patterns 131 and the first end of the flexible cable linkage 133 for encapsulation, thus forming a first package. Furthermore, the second mold cap 152 covers respective top surfaces of the second set of conductive patterns 132 and the second end of the flexible cable linkage 133 for encapsulation, thus forming a second package. In some other embodiments, the at least one second-type electronic component 122 may be mounted on the front surface of the second package substrate 112, and thus the second mold cap 152 covers respective top surfaces of the second set of conductive patterns 132, the at least one second-type electronic component 122 and the second end of the flexible cable linkage 133 for encapsulation.

In the embodiment shown in FIGS. 1F and 1G, the first mold cap 151 is isolated from the second mold cap 152 by the interconnect portion 115 of the base package substrate 101 and the flexible cable linkage 133. Furthermore, the first mold cap 151 is formed of a molding material different from that of the second mold cap 152. Particularly, the first mold cap 151 is formed of an epoxy molding compound having a dielectric coefficient lower than that of the second mold cap 152. In some embodiments, the first mold cap 151 may be formed from materials such as epoxy resin, epoxy acrylate or other polymer composite materials. The first mold cap 151 may be non-conductive, and may provide structural support and environmentally protect the first-type electronic components 121 from external elements and contaminants. The second mold cap 152 may contain a dielectric material having a high dielectric constant, such as ajinomoto build-up film, pre-preg, glass, ceramic, silicon, copper clad laminate, quartz, and Teflon. The material of the second mold cap 152 may increase transmission and reception ability of the underlying second-type electronic components 122, which are antennas in this embodiment.

Furthermore, as shown in FIG. 1G, the second mold cap 152 may include one or more stages each aligned with one of the one or more antennas 122. In this embodiment, each of the stages may be shaped as a truncated pyramid. Particularly, each of the antennas 122 may be aligned with a truncated pyramid shaped stage. In some other embodiments, the second mold cap 152 above the antennas 122 may have a variety of shapes such as diamond, hemisphere, semi-elliptical, or lens shape. The shape of the second mold cap 152 may increase transmission and reception area of the corresponding antennas 122, and the shapes of the second mold cap 152 may optimize refraction, diffraction and reflection characteristics of radiofrequency signals to improve a transmission and reception rate of the antennas 122, thus allowing the second package to have an improved antenna performance.

It should be noted that the above-mentioned process is exemplarily described in FIG. 1G with reference to one of the base package substrates 101, however, the same or similar process may be applied to the other base package substrates 101 of the package substrate strip 100. As shown in FIG. 1F, the mold chase 140 may be attached onto each of the base package substrates 101 of the package substrate strip 100 at the same time, and then first mold caps 151 and second mold caps 152 are formed on each of the base package substrates 101.

Particularly, the first mold caps 151 and the second mold caps 152 may be formed at the same time. Still referring to FIG. 1F, the mold chase 140 attached on the package substrate strip 100 may include multiple first cavities 141 and multiple second cavities 142 which form columns, and the columns of the first cavities 141 and the columns of the second cavities 142 are isolated from each other. When forming the first mold caps 151 and second mold caps 152, different molding materials may be injected into the columns of the first cavities 141 and the columns of the second cavities 142 respectively, forming columns of first mold caps 151 and columns of second mold caps 152 at the same time. Since the columns of the first cavities 141 and the columns of the second cavities 142 of the mold chase 140 are isolated from each other, the different molding materials injected into the first and second cavities 142 and 142 respectively may not flow into the adjacent column of cavities, thus allowing the first and second mold caps 151 and 152 with different material to form within the first and second cavities 141 and 142 at the same time. In this way, for each unit of the package substrate strip 100, i.e., the base package substrate, the components and structures on the first package substrate 111 and on the second package substrate 112 can be encapsulated at the same time, forming the first package and the second package which are electronically connected with the flexible cable linkage 133. Afterwards, the first package and the second package may be mounted onto external devices together instead of being mounted separately, which may significantly simplify the fabrication process and save cost.

Next, as shown in FIG. 1H, a plurality of solder bumps 161 may be formed on a back surface of each of the first package substrates 111. The solder bumps 161 may be used for attaching the first package substrate 111 onto an external device such as a printed circuit board, and are electrically coupled to the interconnect wires 113 in the first package substrate 111 and thus to the first-type electronic components 121 mounted thereon.

Next, the package substrate strip 100 may be singulated into pieces each corresponding to a unit of the strip 100, i.e., the base package substrates 101 are singulated from the package substrate strip 100 with structures thereon. FIG. 1I is a top view of the base package substrate 101 singulated from the package substrate strip 100 and structures thereon, and FIG. 1J is a cross-sectional view of the base package substrate 101 and structures thereon along line AA′ shown in FIG. 1I. As shown in FIGS. 1I and 1J, the singulation may be conducted along boundaries of the first package substrate 111 or the second package substrate 112. After the singulation, each base package substrate 101 includes one first package substrate 111, one second package substrate 112 with respective structures thereon, and a flexible cable linkage 133 electronically connecting the first package substrate 111 and the second package substrate 112. During the singulation process, the interconnect portion 115 may be removed from each of the base package substrates 101, and thus an electronic package assembly 180 is formed. For example, a saw may be used to cut the package substrate strip 100, and each base package substrate 101 may be cut from its back side at the interconnect portions 115 till its front surface. In this way, the interconnection portion 115 may be removed from the base package substrate 101, thereby separating it into two pieces, i.e., the first package substrate 111 and the second package substrate 112, which are only connected through the flexible cable linkage 133. It should be noted that the flexible cable linkages 133 connecting the first and second sets of conductive patterns 132 should not be cut during the singulation process and the removing process of the interconnect portions 115. In some embodiments, the interconnect portions 115 may be removed by a technique from at least one of milling, drilling, pinching, etching or their combinations. In some other embodiments, tiny and shallow grooves may be formed in advance at the boundaries of the interconnect portions 115, and the interconnect portions 115 may be easily broken from the base package substrates 101 along the tiny grooves.

Still referring to FIG. 1J, to be more specific, the electronic package assembly 180 may include the first package and the second package which are electronically connected with each other by the flexible cable linkage 133. The first package further includes the first package substrate 111 having the first set of conductive patterns 131 on the front surface of the first package substrate 111, at least one first-type electronic component 121 mounted on the front surface of the first package substrate 111, and the first mold cap 151 formed on the front surface of the first package substrate 111 and encapsulating the first set of conductive patterns 131 and the at least one first-type electronic component 121. The second package further includes the second package substrate 112 having the second set of conductive patterns 132 on the front surface of the second package substrate 112, at least one second-type electronic component 122 mounted on or in the second package substrate 112, and the second mold cap 152 formed on the front surface of the second package and encapsulating the second set of conductive patterns 132 and the at least one second-type electronic component 122. Furthermore, the first set of conductive patterns 131 and the second set of conductive patterns 132 are formed on the same side of the flexible cable linkage. The first end of the flexible cable linkage 133 may be attached on the front surface of the first package substrate 111 which is encapsulated by the first mold cap 151, and the second end of the flexible cable linkage 133 may be attached on the front surface of the second package substrate 112 which is encapsulated by the second mold cap 152, thus electrically connecting the first set of conductive patterns 131 with the second set of conductive patterns 132 to enable the electrical connection between the first package and second package.

The electronic package assembly 180 may be mounted to an external device. For example, as shown in FIG. 1K, the flexible cable linkage 133 of the electronic package assembly 180 may be bended to an angle of 90° to mount the first package and the second package onto two side surfaces of the external device that are perpendicular to each other. In some other embodiments, the flexible cable linkage 133 may be bended to any other suitable angle from 0.1° to 180° according to various layouts of the semiconductor devices.

In some embodiments, the electronic package assembly 180 can be applied in any electronic devices which desire a flexible arrangement and a reduced processing cost, such as in highly integrated portable devices or the like.

In the embodiment shown in FIGS. 1A to 1K, the step of removing the interconnect portion 115 from the base package substrate 101 is implemented after the step of forming a first mold cap 151 within the first cavity 141 and a second mold cap 152 within the second cavity 142. In some other embodiments, the step of removing the interconnect portion 115 from the base package substrate 101 is implemented prior to the step of attaching a mold chase 140 having a first cavity 141 and a second cavity 142 on the front surface of the base package substrate 101.

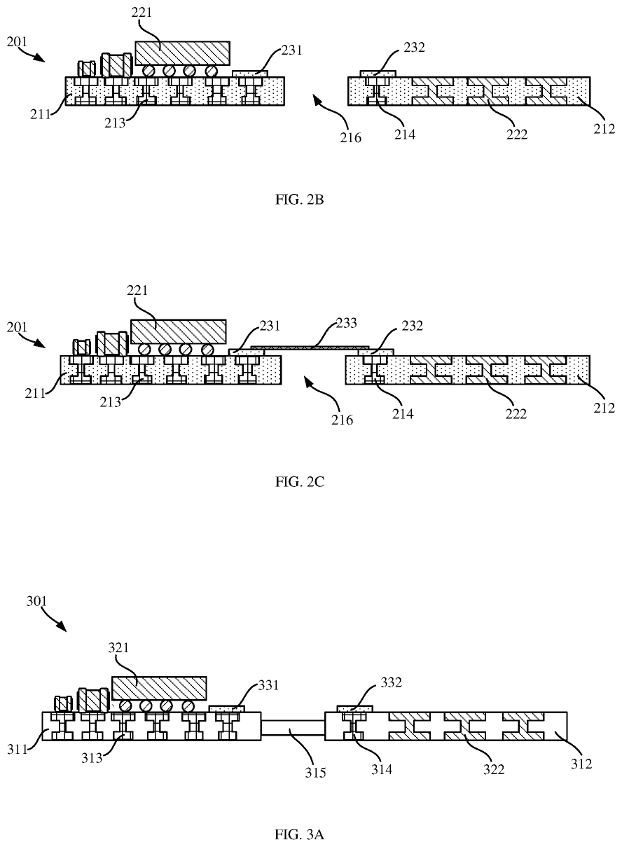

FIGS. 2A to 2C illustrate a portion of various steps of a method for forming an electronic package assembly according to a second embodiment of the present application. As can be appreciated, a plurality of units of package substrates may be provided in a package substrate strip such that a plurality of electronic package assemblies may be formed using the same processing. In this embodiment, each of the units of package substrates may have the same or similar structure, which may be referred to as a base package substrate. FIG. 2A is a top view of the package substrate strip 200 and FIG. 2B is a cross-sectional view of one of the base package substrates 201 along line BB′ shown in FIG. 2A. As shown in FIGS. 2A and 2B, each base package substrate 201 includes a first package substrate 211 with embedded interconnect wires 213, a second package substrate 212 with embedded interconnect wires 214, and an interconnect portion 215 between the first package substrate 211 and the second package substrate 212. The second package substrate 212 further includes at least one second-type electronic component 222 mounted in the second package substrate 212. Next, the interconnect portion 215 may be removed from the base package substrate 201 to form various openings 216 in the package substrate strip 200. However, since the plurality units of the package substrate strip 200 are not singulated from each other, the following steps may still be performed on the package substrate strip 200 rather than on separated units. Then, a first set of conductive patterns 231 and at least one first-type electronic component 221 may be mounted on the front surface of each of the first package substrate 211, and a second set of conductive patterns 232 may be formed on the front surface of each of the second package substrate 212. In some other embodiments, the interconnect portion 215 may be removed from the base package substrate 201 after the first-type electronic components 221, the first and second set of conductive patterns 231 and 232 are mounted or formed onto the front surface of the base package substrate 201. It should be noted that the structures formed on the first package substrate 211 and the second package substrate 212 according to FIG. 2B are omitted in FIG. 2A for simplicity.

Next, as shown in FIG. 2C, a flexible cable linkage 233 is attached onto the front surface of the first package substrate 211 and the second package substrate 212 across the opening 216 to electrically connect the first set of conductive patterns 231 with the second set of conductive patterns 232. Since the interconnect portion 215 may be removed before attachment of the flexible cable linkage 233 connecting the first and second set of conductive patterns 231 and 232, the flexible cable linkage 233 may not be damaged when removing the interconnect portion 215. It should be noted that the following processes are exemplarily described with reference to one of the base package substrates 201, however, the same or similar processes may be applied to the other base package substrates 301 from the package substrate strip 200.

After taking the steps illustrated in FIGS. 2A to 2C, the method may include the similar steps illustrated in FIGS. 1E to 1K, which will not be elaborated in detail here for simplicity. Main steps of the method includes: attaching a mold chase having a first cavity and a second cavity on the front surface of the base package substrate to align the first cavity with the first package substrate and align the second cavity with the second package substrate and forming a first mold cap within the first cavity and a second mold cap within the second cavity by injecting into the first cavity and the second cavity respective molding materials, and the first mold cap is isolated from the second mold cap by the interconnect portion of the base package substrate; singulating the base package substrate from the package substrate strip with structures thereon and thus forming an electronic package assembly. The further details of the steps of the method may be similar to those illustrated in the steps illustrated in FIGS. 1E to 1K.

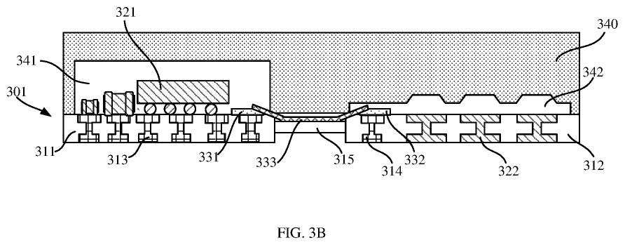

FIGS. 3A and 3B illustrate a portion of various steps of a method for forming an electronic package assembly according to a third embodiment of the present application. A package substrate strip having a plurality of units is provided. In this embodiment, each of the units may have the same or similar structures and may be referred to as a base package substrate 301. FIG. 3A is a cross-sectional view of a base package substrate 301. It should be noted that the following processes are exemplarily described with reference to one of the base package substrates 301, however, the same or similar processes may be applied to the other base package substrates 301 from the package substrate strip.

As shown in FIG. 3A, the base package substrate 301 includes a first package substrate 311 with embedded interconnect wires 313, a second package substrate 312 with embedded interconnect wires 314, and an interconnect portion 315 between the first package substrate 311 and the second package substrate 312. The first package substrate 311 further includes at least one first-type electronic component 321 and a first set of conductive patterns 331 mounted or formed on the front surface of the first package substrate 311. The second package substrate 312 further includes at least one second-type electronic component 322 mounted in the second package substrate 312 and a second set of conductive patterns 332 formed on the front surface of the second package substrate 312. In the embodiment, the base package substrate 301 includes a recess on its front surface that extends across the interconnect portion 315. In some preferred embodiments, the base package substrate 301 may also include a recess on its back surface that extends across the interconnect portion 315.

As shown in FIG. 3B, a flexible cable linkage 333 is attached onto the front surface of the base package substrate 301 and across the interconnect portion 315 to electrically connect the first set of conductive patterns 331 with the second set of conductive patterns 332. Next, a mold chase 340 having a first cavity 341 and a second cavity 342 is attached on the front surface of the base package substrate 301 to align the first cavity 341 with the first package substrate 311 and align the second cavity 342 with the second package substrate 312. Due to the recess on the front surface of the interconnect portion 315, there may exist a gap between a bottom surface of the mold chase 340 and a top surface of the interconnect portion 315, which may be used to accommodate the central part of the flexible cable linkage 333. In this way, the flexible cable linkage 333 may be exposed to a smaller external pressure and experience less deformation when the mold chase 340 is being attached onto the front surface of the base package substrate 301, so as to avoid damage to the flexible cable linkage 333.

After taking the steps illustrated in FIGS. 3A and 3B, the method may include the similar steps illustrated in FIGS. 1F to 1K, which will not be elaborated in detail here for simplicity. Main steps of the method include: forming a first mold cap within the first cavity and a second mold cap within the second cavity by injecting into the first cavity and the second cavity respective molding materials, wherein the first mold cap is isolated from the second mold cap by the interconnect portion of the base package substrate; singulating the base package substrate from the package substrate strip with structures thereon. During the singulation process, the rest of the interconnect portion may be removed from the base package substrate, and thus an electronic package assembly is formed. Due to the recess on the front surface of the interconnect portion in the prior step, it is easier to remove the rest of the interconnect portion from the base package substrate. The further details of the steps of the method may be similar to those steps illustrated in FIG. 1F to 1K.

While the exemplary method for forming an electronic package assembly of the present application is described in conjunction with corresponding figures, it will be understood by those skilled in the art that modifications and adaptations to the method may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for making an electronic package assembly, the method comprising:
providing a base package substrate, wherein the base package substrate comprises a first package substrate having a first set of conductive patterns, a second package substrate having a second set of conductive patterns, and an interconnect portion between the first package substrate and the second package substrate, and wherein the first and second sets of conductive patterns are both formed on a front surface of the base package substrate;
attaching a flexible cable linkage onto the front surface of the base package substrate and across the interconnect portion to electrically connect the first set of conductive patterns with the second set of conductive patterns;
attaching a mold chase having a first cavity and a second cavity on the front surface of the base package substrate to align the first cavity with the first package substrate and align the second cavity with the second package substrate;
forming a first mold cap within the first cavity and a second mold cap within the second cavity by injecting into the first cavity and the second cavity respective molding materials, wherein the first mold cap is isolated from the second mold cap by the interconnect portion of the base package substrate; and
removing the interconnect portion from the base package substrate.

2. The method of claim 1, wherein the first mold cap is formed of a molding material different from that of the second mold cap.

3. The method of claim 2, wherein the first mold cap is formed of an epoxy molding compound having a dielectric coefficient lower than that of the second mold cap.

4. The method of claim 1, wherein forming a first mold cap within the first cavity and a second mold cap within the second cavity comprises:
forming the first mold cap and the second mold cap at the same time.

5. The method of claim 1, wherein forming a first mold cap within the first cavity and a second mold cap within the second cavity comprises:
encapsulating the first set of conductive patterns with the first mold cap and encapsulating the second set of conductive patterns with the second mold cap.

6. The method of claim 1, wherein the base package substrate further comprises at least one first-type electronic component mounted on the front surface of the first package substrate, and at least one second-type electronic component mounted on the front surface of the second package substrate; and wherein forming a first mold cap within the first cavity and a second mold cap within the second cavity comprises:
encapsulating the first set of conductive patterns and the at least one first-type electronic component with the first mold cap, and encapsulating the second set of conductive patterns and the at least one second-type electronic component with the second mold cap.

7. The method of claim 1, wherein the base package substrate further comprises at least one first-type electronic component mounted on the front surface of the first package substrate, and at least one second-type electronic component formed in the second package substrate; and wherein forming a first mold cap within the first cavity and a second mold cap within the second cavity comprises:
encapsulating the first set of conductive patterns and the at least one first-type electronic component with the first mold cap, and encapsulating the second set of conductive patterns with the second mold cap.

8. The method of claim 1, wherein the base package substrate comprises a recess on its front surface that extends across the interconnect portion.

9. The method of claim 1, wherein the step of removing the interconnect portion from the base package substrate is implemented prior to the step of attaching a mold chase having a first cavity and a second cavity on the front surface of the base package substrate.

10. The method of claim 1, wherein the step of removing the interconnect portion from the base package substrate is implemented is after the step of forming a first mold cap within the first cavity and a second mold cap within the second cavity.

11. The method of claim 1, wherein the first and second sets of conductive patterns are both adjacent to the interconnect portion of the base package substrate.

12. An electronic package assembly, comprising:
a first package, comprising:
a first package substrate having a first set of conductive patterns formed on a front surface of the first package substrate; and
a first mold cap formed on the front surface of the first package substrate and encapsulating the first set of conductive patterns;
a second package separated from the first package, the second package comprising:
a second package substrate having a second set of conductive patterns formed on a front surface of the second package substrate; and
a second mold cap formed on the front surface of the second package substrate and encapsulating the second set of conductive patterns; and
a flexible cable linkage comprising a first end attached on the front surface of the first package substrate and encapsulated by the first mold cap, and a second end attached on the front surface of the second package substrate and encapsulated by the second mold cap, the flexible cable linkage electrically connecting the first set of conductive patterns with the second set of conductive patterns.

13. The electronic package assembly of claim 12, wherein the first mold cap is formed of a molding material different from that of the second mold cap.

14. The electronic package assembly of claim 13, wherein the first mold cap is formed of an epoxy molding compound having a dielectric coefficient lower than that of the second mold cap.

15. The electronic package assembly of claim 12, wherein the first set of conductive patterns and the second set of conductive patterns are formed on a same side of the flexible cable linkage.

16. The electronic package assembly of claim 12, wherein the first package further comprises at least one first-type electronic component mounted on the front surface of the first package substrate, and the second package further comprises at least one second-type electronic component mounted on the front surface of the second package substrate; and wherein the first set of conductive patterns and the at least one first-type electronic component are encapsulated by the first mold cap, and the second set of conductive patterns and the at least one second-type electronic component are encapsulated by the second mold cap.

17. The electronic package assembly of claim 12, wherein the first package further comprises at least one first-type electronic component mounted on the front surface of the first package substrate, and the second package further comprises at least one second-type electronic component formed in the second package substrate; and wherein the first set of conductive patterns and the at least one first-type electronic component are encapsulated by the first mold cap, and the second set of conductive patterns are encapsulated by the second mold cap.

18. The electronic package assembly of claim 17, wherein the at least one second-type electronic component comprises one or more antennas, and the second mold cap comprises one or more stages each aligned with one of the one or more antennas.
